(19) United States
(12) Patent Application Publication
(10) Pub. No.: US 2025/0015560 A1
(43) Pub. Date: Jan. 9, 2025

(54) SEMICONDUCTOR LASER AND MODULE DEVICE

(71) Applicant: Nippon Telegraph and Telephone Corporation, Tokyo (JP)

(72) Inventors: Manabu Mitsuhara, Tokyo (JP); Wataru Kobayashi, Tokyo (JP)

(21) Appl. No.: 18/711,987

(22) PCT Filed: Jan. 11, 2022
(86) PCT No.: PCT/JP2022/000487

§ 371 Date: May 21, 2024

(51) Int. Cl. H01S 5/06; H01S 5/22; H01S 5/343

(52) U.S. Cl. CPC H01S 5/0612; H01S 5/22; H01S 5/343

(57) ABSTRACT

A semiconductor laser of the present invention includes a first cladding layer, an active layer, and a second cladding layer sequentially provided on a substrate, includes a ridge portion arranged in a waveguide direction in the second cladding layer and a heater arranged near the ridge portion, and has an oscillation wavelength of 1.6 μm to 2.4 μm. Furthermore, a first guide layer and a second guide layer are provided between the first cladding layer and the active layer and between the active layer and the second cladding layer, respectively, a diffraction grating is provided at a boundary between the first cladding layer and the first guide layer or a boundary between the second cladding layer and the second guide layer, and an insulating film is provided on a surface of the second guide layer excluding the ridge portion, and the heater is arranged on the insulating film.

### CROSS-REFERENCE TO RELATED APPLICATIONS

This application is a national phase entry of PCT Application No. PCT/JP2022/000487, filed on Jan. 11, 2022, which application is hereby incorporated herein by reference.

### TECHNICAL FIELD

The present invention relates to a semiconductor laser and a module element capable of performing wavelength sweep at high speed in a wide range.

### BACKGROUND

A gas measurement system using light allows for concentration measurement with high accuracy in real time, and is used in various fields such as component analysis of a gas discharged from a factory or a gas in the atmosphere, inspection of gas leakage from a device or a pipe, and inspection of Helicobacter pylori in medical care.

The gas measurement system using light basically utilizes a phenomenon in which a gas molecule exhibit optical absorption at a certain wavelength that varies depending on the gas species. Gas absorption lines can be roughly classified into fundamental tones in which only one vibration energy is involved, and overtones and combination tones in which a plurality of vibration energies is involved. In many gas species, fundamental tones exhibit significant optical absorption in a wavelength region of 4 μm or more, whereas overtones and combination tones exhibit significant optical absorption in a wavelength region of 3 μm or less.

FIG. 4 illustrates a wavelength range and intensity of an absorption line of a gas species that exhibits significant optical absorption in a wavelength range of 1.6 μm to 2.4 μm in wavelength (hereinafter referred to as the “wavelength range around 2 μm”). In the wavelength range around 2 μm, there are many absorption lines of gas species such as methane, carbon dioxide, nitrous oxide, carbon monoxide, hydrochloric acid, water, and ammonia, which are related to a greenhouse effect and environmental pollution. In the drawing, gas species surrounded by a broken line are related to the greenhouse effect, and gas species surrounded by a dotted line are related to environmental pollution. A hatched area indicates an optical communication wavelength band.

Gas absorption lines have a narrow line width, and two or more absorption lines are crowded in a narrow wavelength region for each gas species. One absorption line is normally used in gas measurement, and light from a light source used in gas measurement is therefore desired to have a narrow line width and a single wavelength. Semiconductor lasers make it relatively easy to obtain light emission at a single wavelength, are small in size, and use less power compared with gas lasers and solid-state lasers, and thus are widely used as light sources for gas measurement.

In order to apply a semiconductor laser used for gas measurement to the wavelength range around 2 μm, semiconductor lasers (hereinafter referred to as “around-2 μm wavelength band lasers”) on InP substrates that oscillate at a single wavelength have been researched and developed, and some of such lasers have been already put to practical use and are commercially available (e.g., Non Patent Literature 1, Non Patent Literature 2, and Non Patent Literature 4).

The around-2 μm wavelength band lasers use, as an active layer, a multiple quantum well structure (MQW) having a well layer constituted by InGaAs or InGaAsP to which compressive strain is applied on an InP substrate, thereby allowing for oscillation in a wavelength band longer than an optical fiber communication band, and furthermore, a structure of a DFB laser or a DBR laser, which has been actually used as a laser for optical fiber communication, is applied to allow for oscillation at a single wavelength.

By using InAs for the well layer, it is possible to produce a laser having an oscillation wavelength of 2.3 μm (e.g., Non Patent Literature 3). By using a structure in which InGaAsSb is used as a well layer, it is possible to cover a wavelength region of 2.2 μm to 2.4 μm. Details will be described below.

As illustrated in FIG. 5, a conventional semiconductor laser 30 that oscillates at a wavelength around 2 μm on an InP substrate includes an n-type InP substrate 301, an n-type InP cladding layer 302, InGaAsP guide layers 303_1 and 303_2, an active layer 304, InGaAsP guide layers 305_2 and 305_1, a p-type InP cladding layer 306, and a p-type InGaAs contact layer 307, and further includes an n-type electrode 308 and a p-type electrode 309.

For the active layer 304, an MQW having a well layer and a barrier layer constituted by InGaAs or InGaAsSb is used, and large compressive strain is applied to the well layer. Here, the layer configuration excluding the MQW is substantially the same as the layer configuration of a laser used in optical fiber communication, and the 2 μm-band laser on the InP substrate can be produced in a similar manner to a laser for optical fiber communication.

In the semiconductor laser 30, an increase in emission wavelength is achieved by using an MQW having a well layer to which large compressive strain is applied as described above. The emission wavelength of the MQW is basically around a band gap wavelength of the well layer.

FIG. 6 illustrates a change in band gap wavelength caused by a change in film thickness of the well layer of the MQW of the 2 μm-band laser on the InP substrate. Here, InGaAs or InGaAsSb (Sb molar composition ratio: 0.1, 0.2, or 0.3) is used for each of the well layer and the barrier layer, and the compressive strain of the well layer is set to 2%. The barrier layer is lattice-matched to the InP, and the Sb molar composition ratio of the barrier layer is equal to the Sb molar composition ratio of the well layer.

As illustrated in FIG. 6, by using InGaAsSb for the well layer, a band gap wavelength of 2.2 μm to 2.4 μm can be obtained. By using an MQW including this InGaAsSb well layer as an active layer and providing a diffraction grating capable of obtaining an oscillation wavelength around the band gap wavelength, it is possible to produce a DFB laser or a DBR laser that oscillates at a single wavelength in a wavelength region of 2.2 μm to 2.4 μm.

FIG. 7 illustrates an oscillation spectrum of a DFB laser having an InGaAs/InGaAs MQW as an active layer produced on an InP substrate (injection current: 60 mA). An oscillation peak has a line width of about 0.1 to 0.2 nm, and a side mode suppression ratio (SMSR) of 30 dB.

On the other hand, in gas species to be measured, for example, the absorption line (dotted line in the drawing) of carbon dioxide (¹²C¹⁶O₂) and the absorption line (solid line in the drawing) of water (¹H₂¹⁶O) have a narrow line width around 2.05 μm in wavelength, and a large number of crowded absorption lines are observed in a narrow wavelength range as illustrated in FIG. 8. Here, the absorption lines have been acquired using high-resolution transmission molecular absorption database (HITRAN). The intervals between the absorption lines are about 0.5 nm for carbon dioxide and about 2 to 3 nm for water.

Thus, in gas measurement, the line width of the oscillation spectrum of a semiconductor laser is narrower than the wavelength intervals of the absorption lines, and when the semiconductor laser is used for gas measurement, the oscillation wavelength of the laser is swept (changed) in the vicinity of a gas absorption line, which is one of the absorption lines selected as a target, so that a change in light transmittance can be analyzed.

The oscillation wavelength of the semiconductor laser changes in accordance with the temperature of a heat sink on which the semiconductor laser is mounted and the injection current for the semiconductor laser. As compared with the temperature of the heat sink, the injection current causes faster time response of the laser wavelength change. Thus, in gas measurement, the injection current is normally changed to sweep the wavelength of the laser.

FIG. 9 illustrates changes in oscillation wavelength caused by the heat sink temperature and the injection current of the DFB laser. Here, the DFB laser has a resonator length of 900 μm, an InGaAs/InGaAs MQW on the InP substrate as an active layer, and an oscillation wavelength set to around 2.05 μm. At each of heat sink temperatures (15° C., 25° C., 35° C., and 45° C.), the injection current for the laser is increased from 50 mA to 150 mA, so that the oscillation wavelength shifts to a longer wavelength side by about 0.2 nm.

Since both the line width of the gas absorption line and the line width of the oscillation spectrum of the laser are narrow, wavelength sweep can be performed on one gas absorption line with the shift amount of about 0.2 nm of the semiconductor laser, and only one target gas absorption line can be selected and measured by using this change in transmittance.

This change in oscillation wavelength caused by the injection current is mainly attributable to a change in effective refractive index resulting from an increase in temperature in the vicinity of the active layer caused by Joule heat generated by a current. At this time, a heat capacity of the laser alone is small, and the oscillation wavelength of the laser changes in a shorter time as compared with a case of changing the temperature of the heat sink. Furthermore, in a case of measuring the concentration of trace gas, an f detection, a 2f detection, or the like can be used in which the light source is modulated at a certain frequency and a signal from a detector is subjected to phase-sensitive detection at a frequency that is an integral multiple of the frequency of the signal.

On the other hand, in the case of changing the temperature of the heat sink, the temperature can be changed in a wider range than in the case of changing the injection current. FIG. 10 illustrates a change in oscillation wavelength when the injection current for the DFB laser is constant and the temperature of the heat sink is changed. The oscillation wavelength of the laser is changed by about 2 nm when the temperature of the heat sink is changed by 20° C., and the rate of change in oscillation wavelength is about 0.1 nm/° C.

This change in oscillation wavelength caused by the temperature is mainly due to a change in effective refractive index caused by the temperature, and is about the same as long as the material can be produced on the InP substrate. Therefore, in a case of a laser having a different oscillation wavelength, the rate of change in oscillation wavelength caused by the temperature of the heat sink is about the same as that in the case of this laser that oscillates at a wavelength around 2.05 μm.

As illustrated in FIG. 11, not only one gas absorption line but also a plurality of gas absorption lines can be measured by changing the temperature of the heat sink. Here, light from the DFB laser was made incident on a gas cell enclosing carbon dioxide while the temperature of the heat sink was being changed, and changes in transmittance was observed (solid line in the drawing). As compared with the spectrum of the gas absorption line (dotted line in the drawing), the transmittance changes in accordance with the wavelength and intensity of the gas absorption line, and thus it is understood that a plurality of gas absorption lines can be measured.

Thus, by sweeping the laser light across a wide wavelength range, it is possible to measure a plurality of absorption lines for one gas species, and improve the accuracy of gas measurement. Furthermore, by expanding the wavelength range in which sweeping can be performed, a plurality of gas species can be measured by one laser. For example, it is possible to measure gas absorption lines of both carbon dioxide and water (FIG. 8) by setting the oscillation wavelength of the DFB laser to be around 2.047 μm when the temperature of the heat sink is 15° C., and changing the oscillation wavelength by the temperature of the heat sink.

As described above, it is useful to expand the wavelength range in which sweeping can be performed in gas measurement using a semiconductor laser.

### CITATION LIST

### Non Patent Literature

Non Patent Literature 1: M. Mitsuhara and M. Oishi, “Chapter2: 2 μm wavelength lasers employing InP-based strained-layer quantum wells,” in “Long-wavelength infrared semiconductor lasers (ed. H. K. Choi),” Wiley, New Jersey, 2004.
Non Patent Literature 2: T. Sato, M. Mitsuhara, T. Watanabe, K. Kasaya, T. Takeshita and Y. Kondo, “2.1-μm-wavelength InGaAs multiple-quantum-well distributed feedback lasers grown by MOVPE,” IEEE Journal of Selected Topics in QUuantum Electronics, VOL. 13, NO. 5, 2007, 1079-1082.
Non Patent Literature 3: T. Sato, M. Mitsuhara, N. Nunoya, T. Fujisawa, K. Kasaya, F. Kano and Y. Kondo, “2.33-μm-wavelength distributed feedback lasers with InAs—In0.53Ga0.47As multiple-quantum wells on InP substrates,” IEEE Photonics Technology Letters, VOL. 20, NO. 12, 2008, 1045-1047.
Non Patent Literature 4: https://www.ntt-electronics.com/product/gas_sensing/gas_sensing.html SUMMARY

### Technical Problem

However, in a gas measurement system, in a case of wavelength sweep by changing the temperature of the heat sink, it is difficult to perform measurement at high speed. Details thereof will be described below.

In a case of a general laser module, a semiconductor laser, a heat sink, a submount, and a Peltier element are sequentially mounted. The temperature of the semiconductor laser is measured by a thermistor arranged on the heat sink. In a case of changing the temperature of the heat sink, not only the heat capacity of the semiconductor laser but also the heat capacities of the heat sink, the submount, and the Peltier element are involved in a change in temperature of the semiconductor laser. As a result, the total heat capacity from the semiconductor laser to the Peltier element becomes large, which makes it difficult to change the temperature of the laser in a short time. This therefore poses a problem in that gas measurement requires a lot of time.

Furthermore, in a case where the f detection or the 2f detection is used for gas concentration measurement, it takes time to stabilize the temperature of the semiconductor laser (active layer) by changing the temperature of the heat sink, and thus it is difficult to perform measurement by modulating the light source at a high frequency.

Thus, in measurement in which wavelength sweep is performed by changing the temperature of the heat sink, it is possible to expand the wavelength range over which the laser can sweep, but it is difficult to perform measurement at high speed and modulation measurement at high frequency.

As described above, in measurement in which wavelength sweep is performed by current injection, it is possible to perform measurement at high speed, but it is difficult to expand the wavelength range.

As described above, in gas measurement using a semiconductor laser, measurement at high speed in a wide wavelength range is a challenge to be addressed.

### Solution to Problem

In order to solve the above-described problem, embodiments of the present invention provide a semiconductor laser including: a first cladding layer, an active layer, and a second cladding layer sequentially provided on a substrate; a ridge portion arranged in a waveguide direction in the second cladding layer; and a heater arranged near the ridge portion, in which an oscillation wavelength is 1.6 μm to 2.4 μm.

### Advantageous Effects of Embodiments of the Invention

Embodiments of the present invention provide a semiconductor laser and a module element that perform wavelength sweep at high speed in a wide wavelength range.

### BRIEF DESCRIPTION OF THE DRAWINGS

FIG. 1A is a schematic perspective view illustrating a configuration of a semiconductor laser according to a first embodiment of the present invention.

FIG. 1B is a cross-sectional view taken along line IB-IB′ in the configuration of the semiconductor laser according to the first embodiment of the present invention.

FIG. 1C is a schematic top view illustrating the configuration of the semiconductor laser according to the first embodiment of the present invention.

FIG. 2 is a diagram for illustrating an operation of the semiconductor laser according to the first embodiment of the present invention.

FIG. 3A is a schematic perspective view illustrating a configuration of an optical semiconductor element according to a second embodiment of the present invention.

FIG. 3B is a schematic top view illustrating the configuration of the optical semiconductor element according to the second embodiment of the present invention.

FIG. 4 is a diagram for illustrating gas measurement by a conventional semiconductor laser.

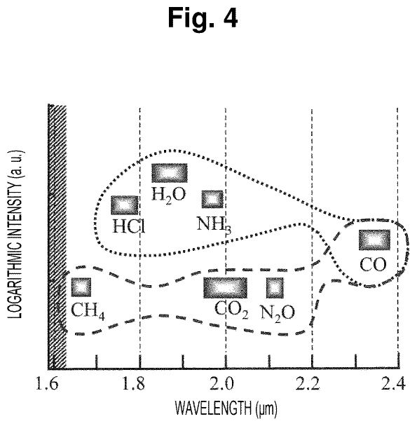

FIG. 5 is a cross-sectional view illustrating a configuration of a conventional semiconductor laser for gas measurement.

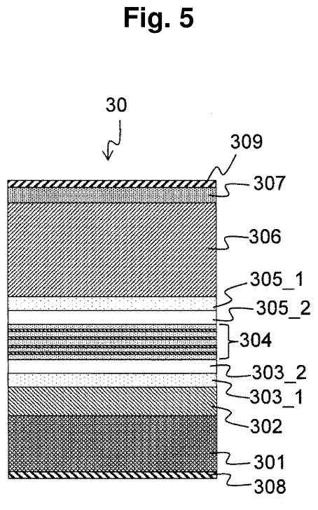

FIG. 6 is a diagram for illustrating the conventional semiconductor laser for gas measurement.

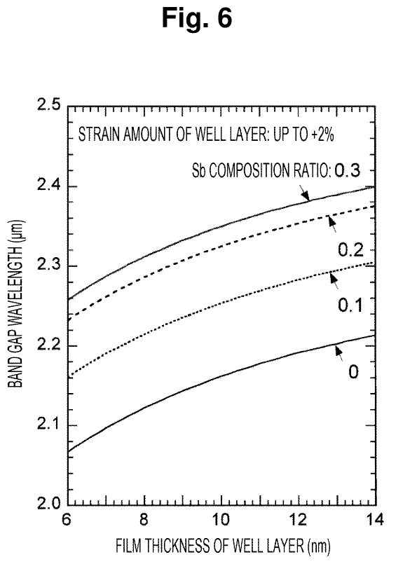

FIG. 7 is a diagram for illustrating the conventional semiconductor laser for gas measurement.

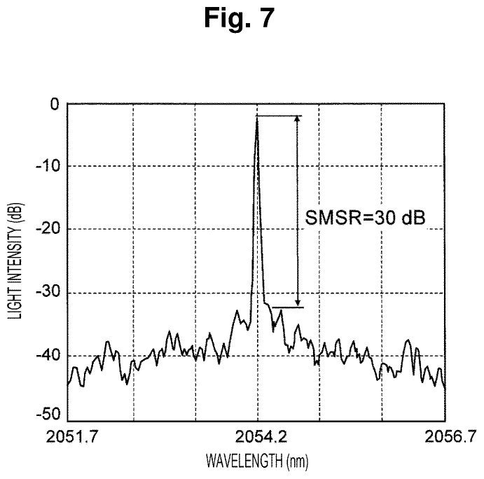

FIG. 8 is a diagram for illustrating the conventional semiconductor laser for gas measurement.

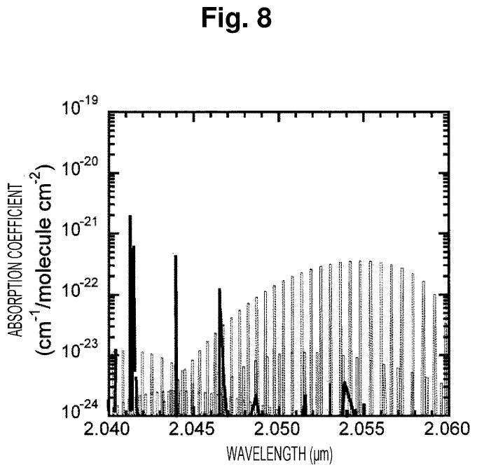

FIG. 9 is a diagram for illustrating the conventional semiconductor laser for gas measurement.

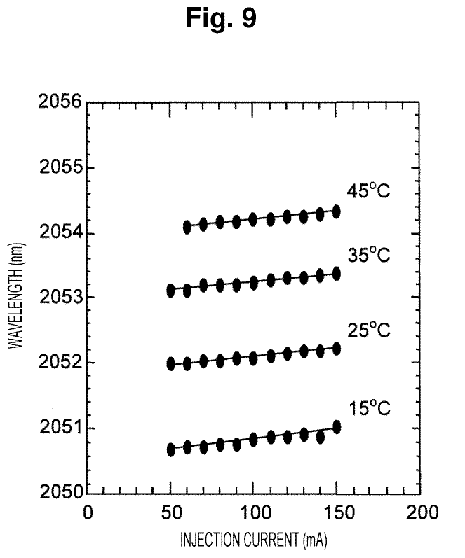

FIG. 10 is a diagram for illustrating the conventional semiconductor laser for gas measurement.

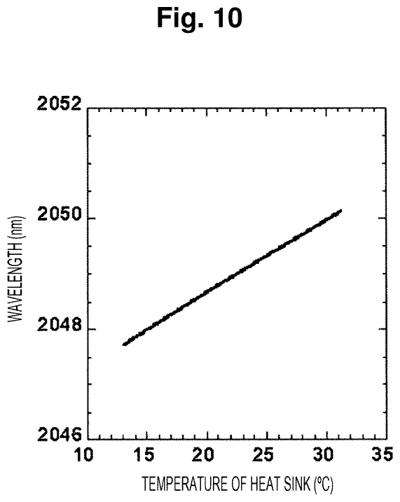

FIG. 11 is a diagram for illustrating the conventional semiconductor laser for gas measurement.

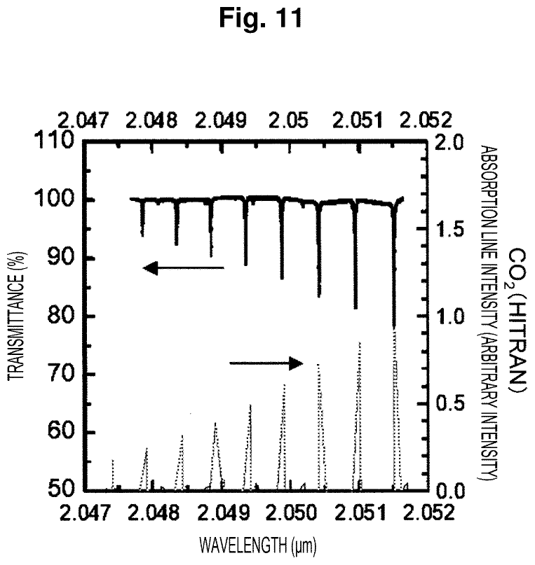

### DETAILED DESCRIPTION OF ILLUSTRATIVE EMBODIMENTS

### First Embodiment

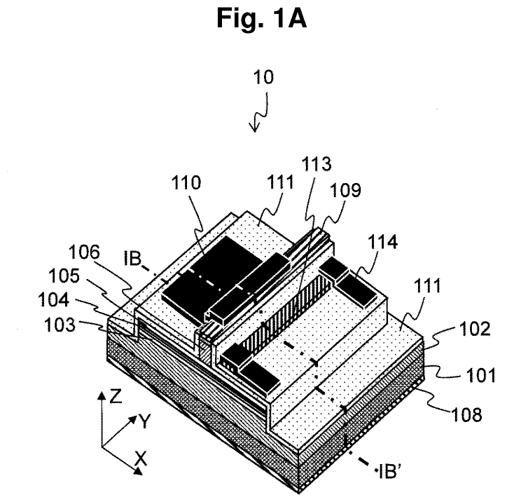

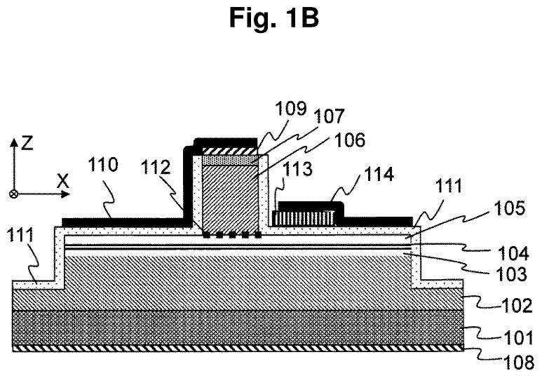

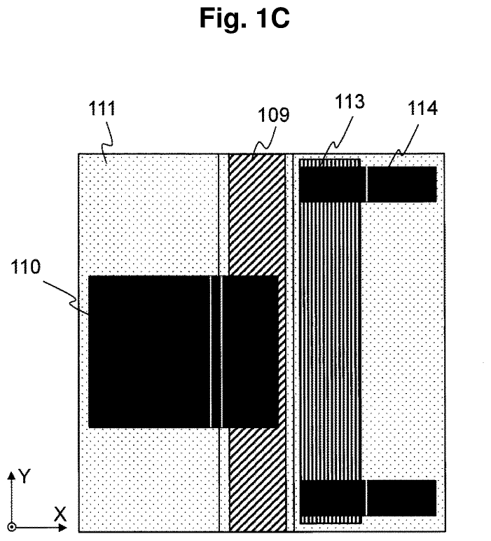

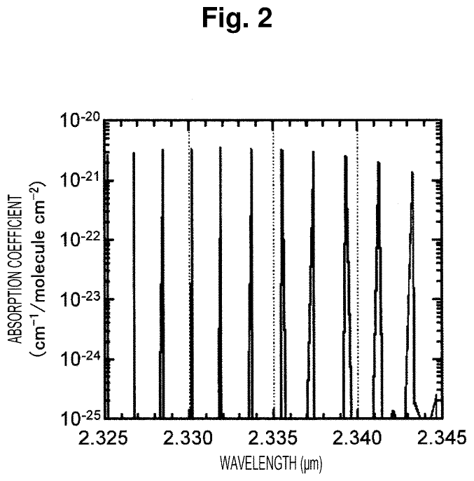

A semiconductor laser according to a first embodiment of the present invention will be described with reference to FIGS. 1A to 2.

### Configuration of Semiconductor Laser

As illustrated in FIGS. 1A to 1C, a semiconductor laser 10 according to the present embodiment has a ridge waveguide structure having a ridge portion, and is sequentially provided with a substrate 101, a first cladding layer 102, a first guide layer 103, an active layer 104, a second guide layer 105, and a second cladding layer 106.

In addition, a diffraction grating 112 is provided at a boundary between the second guide layer 105 and the second cladding layer 106. The diffraction grating 112 has a Bragg wavelength of 2.33 μm.

An n-type InP substrate is used as the substrate 101, and, for example, AuGeNi or Au is provided as an n-type electrode 108 on a back surface.

The first cladding layer 102 is n-type InP, and the first guide layer 103 is InGaAsP (1.15 μm in band gap wavelength, and 0.1 μm in film thickness).

The active layer 104 is a multiple quantum well (MQW), is constituted by a compressively strained InGaAsSb well layer and a tensile-strained InGaAsSb barrier layer, has four periods, and has a layer thickness of 6 to 7 nm. The photoluminescence emission wavelength of the MQW is about 2.33 μm, and is a wavelength near an absorption line of carbon monoxide (¹²C¹⁶O₂) (FIG. 2 described later).

The second guide layer 105 is InGaAsP (1.15 μm in band gap wavelength, and 0.1 μm in film thickness).

The second cladding layer 106 is p-type InP, and has a protrusion extending in a waveguide direction (Y direction in the drawing) and constituting a ridge portion.

A p-type electrode 109 constituted by AuZnNi, Au, or the like and a pad electrode (e.g., Au) 110 are sequentially provided on the second cladding layer 106 via a contact layer 107 constituted by p-type InGaAs or the like.

An insulating film (e.g., SiO₂) 111 is formed on the surface of the semiconductor laser 10, excluding the portion where the p-type electrode 109 is to be formed.

Furthermore, a heater 113 is arranged near the ridge portion in parallel with the ridge portion on the surface of the insulating film 11 on the second guide layer 105. In addition, a pad electrode (e.g., Au) 114 electrically connected to the heater 113 is provided, and is connected to an external power supply (not illustrated) to apply a voltage. Pt is used for the heater 113, and the film thickness is 0.6 μm and the width is 15 μm. Here, the distance between the heater 113 and the ridge portion is 0.2 μm.

Here, an example in which the heater 113 is arranged in parallel with the ridge portion has been described, but the heater 113 may not be arranged in parallel, and is only required to be arranged near the ridge portion.

### Operation of Semiconductor Laser

The semiconductor laser 10 according to the present embodiment is mounted on a semiconductor laser module. The semiconductor laser module is sequentially provided with the semiconductor laser 10 according to the present embodiment, a heat sink, a submount, and a Peltier element.

In gas measurement, the wavelength of a gas absorption line is determined depending on the gas species, and it is therefore necessary to adjust the oscillation wavelength of the semiconductor laser to the wavelength of the gas absorption line to be measured and to stabilize the oscillation wavelength by temperature control. In the present embodiment, in a situation where the temperature of the heat sink is kept constant by the Peltier element, the heater 113 locally changes the temperature around the active layer 104 of the laser, thereby changing the oscillation wavelength.

In a semiconductor laser, a change in oscillation wavelength of a DFB laser caused by the temperature is mainly due to a change in effective refractive index around the active layer, that is, around the diffraction grating (resonance structure), caused by the temperature. Therefore, as the region where the temperature from a heat source such as the heat sink or the heater propagates becomes longer, it takes a longer time to stabilize the temperature around the active layer of the semiconductor laser.

In a conventional case of performing wavelength sweep by changing the temperature of the heat sink by the semiconductor laser, not only the heat capacity of the semiconductor laser but also the heat capacities of the heat sink, the submount, and the Peltier element are involved in a change in and stabilization of the temperature around the active layer, so that it takes a long time to perform the wavelength sweep.

On the other hand, in the present embodiment, the heater 113 is arranged in the semiconductor laser 10, and thus it is possible to relatively reduce dependence of a change in temperature around the active layer 104 on the heat capacities of the heat sink, the submount, and the Peltier element as compared with the conventional semiconductor laser, and increase dependence on the heat capacity of a main body of the semiconductor laser 10. As a result, it is possible to shorten the time required to change and stabilize the temperature around the active layer 104 and shorten the time required for wavelength sweep, and thus gas measurement can be performed at high speed.

Furthermore, in a case where a heater is used in a laser having an embedding structure used in a conventional semiconductor laser on an InP substrate, the heater is arranged near the surface of the second cladding layer, and this results in a longer distance between the heater and the active layer, and a longer region where the temperature of the heater propagates. As a result, it takes a long time to stabilize the temperature around the active layer of the semiconductor laser.

On the other hand, in the semiconductor laser 10 according to the present embodiment, the heater 113 can be arranged near the surface of the second guide layer 105 in the ridge waveguide structure, and it is therefore possible to reduce the distance between the heater 113 and the active layer 104, and reduce the region where the temperature of the heater 113 propagates. As a result, it is possible to shorten the time required to stabilize the temperature around the active layer 104 of the semiconductor laser and shorten the time required for wavelength sweep, and thus gas measurement can be performed at high speed.

In the semiconductor laser 10 according to the present embodiment, in the second guide layer (InGaAsP) 105 exposed in the region excluding the ridge portion, up to a part of the first cladding layer (n-type InP) 102 or the n-type InP substrate 101 may be removed in the region outside the region where the pad electrodes 110 and 114 are arranged. As a result, the second guide layer 105, the active layer 104, and the first guide layer 103 are not provided in the region outside the region where the pad electrodes 110 and 114 are arranged. Here, “outside the region where the pad electrodes are arranged” refers to the opposite side of the ridge portion with respect to each of the pad electrodes 110 and 114.

Thus, the volume of the semiconductor laser 10 is reduced, the heat capacity is reduced, and propagation of heat from the heater 113 to the outside of the region of the laser to be the active layer can be suppressed. As a result, heat conduction from the heater 113 to the region of the laser to be an active layer is improved, and the time required for wavelength sweep can be shortened, and thus gas measurement can be performed at high speed.

### Effects of Semiconductor Laser

Effects of the semiconductor laser 10 according to the present embodiment will be described. For comparison, a conventional case will be described in which no current is applied to the heater in a semiconductor laser that changes (sweeps) the wavelength by changing the temperature of the heat sink, that is, the semiconductor laser 10.

First, in the semiconductor laser 10, an oscillation threshold current is 30 mA when the temperature of the heat sink is 20° C., and the oscillation wavelength is 2.330 μm when the injection current is 100 mA.

Assuming a conventional case of changing the wavelength by changing the temperature of the heat sink, the injection current for the semiconductor laser 10 is made constant at 100 mA, and the temperature of the heat sink is increased from 20° C. to 50° C. As a result, the oscillation wavelength changes from 2.330 μm to 2.333 μm in about 500 milliseconds.

On the other hand, in the semiconductor laser 10 according to the present embodiment, the oscillation wavelength is changed only by the current applied to the heater 113 while the injection current for the laser is kept at 100 mA and the temperature of the heat sink is kept at 20° C. When the current applied to the heater 113 is increased from 0 mA to 210 mA, the oscillation wavelength changes from 2.330 μm to 2.333 μm in about 5 milliseconds.

For example, as illustrated in FIG. 2, an absorption spectrum of carbon monoxide (¹²C¹⁶O₂) has a large number of absorption lines in a wavelength range from 2.325 to 2.345. Thus, in a case of measuring carbon monoxide (¹²C¹⁶O₂) as a target, the oscillation wavelength of the semiconductor laser 10 is swept from 2.330 μm to 2.333 μm as described above, and thus, at least one absorption line among absorption lines of carbon monoxide (¹²C¹⁶O₂) can be swept, and it is possible to acquire a gas concentration by analyzing a change in light transmittance due to the optical absorption.

Thus, in the semiconductor laser according to the present embodiment, the heater is arranged near the active layer, so that wavelength sweep can be performed in a short time as compared with a conventional case of controlling by the temperature of the heat sink. Thus, gas measurement can be performed by performing wavelength sweep in a wide wavelength range at high speed.

Therefore, in the semiconductor laser according to the present embodiment, the time required for gas measurement can be significantly shortened. Furthermore, the light source can be modulated at a high frequency in the gas measurement, and the measurement can be performed with high sensitivity and high accuracy by using the f detection or the 2f detection.

In a case where a heater is used to change the temperature of the laser, the temperature of the heat sink also exercises an effect, and the oscillation wavelength is stabilized when the laser, more specifically, the vicinity of the active layer, reaches a thermal equilibrium. The time it takes to reach the thermal equilibrium can be shortened depending on a positional relationship between the ridge portion and the heater of the semiconductor laser, the shape of the heater, and a configuration such as a separation groove for suppressing heat conduction.

For example, the present embodiment shows an example in which the interval (distance) between Pt as the heater and the ridge portion is 0.2 μm, but the interval (distance) is not limited thereto. It is possible to reduce the interval (distance) between the heater and the ridge portion to about 0.1 μm by shortening the wavelength of the exposure light source, improving the accuracy of positioning a photomask and a wafer, improving an etching technique, or the like.

In a case where the interval (distance) between the heater and the ridge portion is long, heat conduction from the heater to the waveguide decreases, and it is therefore desirable to set the interval (distance) to about 5 μm or less.

### Method of Manufacturing Semiconductor Laser

An example of a method of manufacturing the semiconductor laser 10 according to the present embodiment will be described below.

First, the first cladding layer (n-type InP) 102, the first guide layer (InGaAsP) 103, the active layer (MQW) 104, the second guide layer (InGaAsP) 105, and an InP protective layer are crystal-grown on the n-type InP substrate 101 by metal-organic molecular beam epitaxy.

Next, the InP protective layer is removed, and then the diffraction grating 112 having a Bragg wavelength of 2.33 μm at room temperature is produced by etching on the upper surface of the second guide layer (InGaAsP) 105.

Next, the second cladding layer (p-type InP) 106, the contact layer (p-type InGaAs) 107, and the InP protective layer are regrown on the diffraction grating 112 by metal-organic vapor phase epitaxy.

Next, the second cladding layer (p-type InP) 106, the contact layer (p-type InGaAs) 107, and the InP protective layer are processed by dry etching and wet etching to form a ridge portion.

Next, in the second guide layer (InGaAsP) 105 exposed in the region excluding the ridge portion, a region outside the region where the pad electrodes are arranged in a process to be described later is removed up to a part of the first cladding layer (n-type InP) 102 or the n-type InP substrate 101.

Next, an insulating film is accumulated on the entire upper surface of a wafer, and then the insulating film and the InP protective layer on the contact layer (p-type InGaAs) 107 are removed.

Next, a metal (AuZnNi or Au) to be the p-type electrode 109 is deposited on the contact layer (p-type InGaAs) 107 by resistance heating.

Next, the heater 113 constituted by Pt is formed on the insulating film 11 near the ridge portion by lithography and electron beam deposition.

Next, the p-type electrode 109 and the pad electrodes 110 and 114 of the heater 113, which are constituted by Au, are formed.

Next, the back surface of the n-type InP substrate 101 is polished, and then a metal (AuGeNi or Au) to be the n-type electrode 108 is deposited and annealed for electrode formation.

Next, a ridge waveguide structure having a resonator length of 450 μm is formed by cleavage.

Lastly, a high-reflection film is deposited on one cleavage surface, and an antireflection film is deposited on the other cleavage surface.

Thus, the semiconductor laser 10 is manufactured.

While the present embodiment shows an example of using the configuration of a DFB laser, it is also possible to use the configuration of a DBR laser in which a change in refractive index is used for controlling the oscillation wavelength as in the DFB laser.

While the present embodiment shows an example in which Pt is used for the heater, the metal used for the heater may be any conductor having a large resistance, and, for example, a metal such as a titanium-tungsten alloy (TiW) may be used.

### Second Embodiment

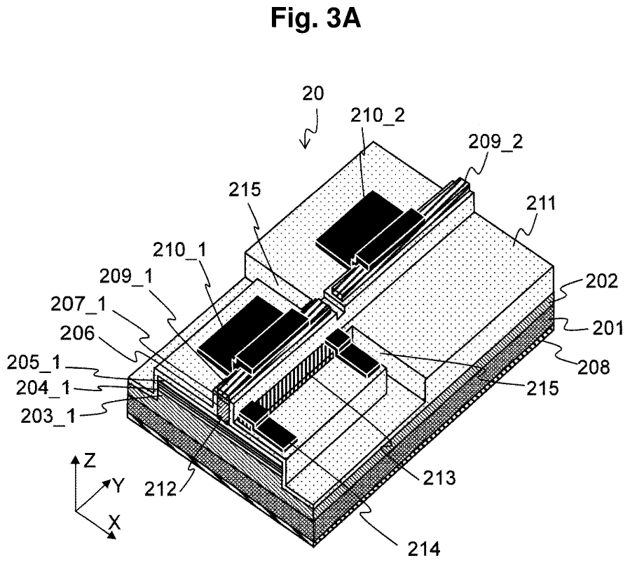

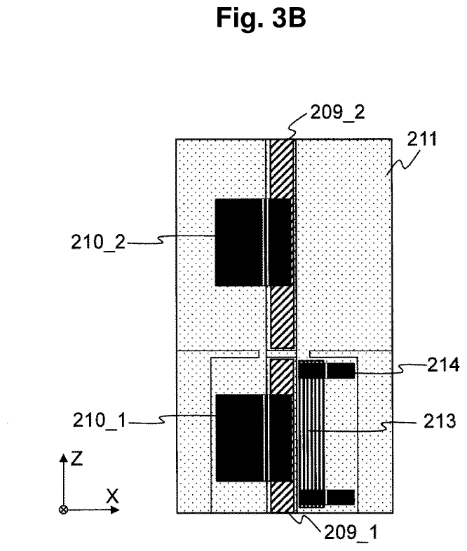

An optical semiconductor element according to a second embodiment of the present invention will be described with reference to FIGS. 3A and 3B.

### Configuration of Optical Semiconductor Element

As illustrated in FIGS. 3A and 3B, an optical semiconductor element 20 according to the present embodiment has a ridge waveguide structure having a ridge portion, and includes a semiconductor laser 20_1 and a semiconductor optical amplifier (SOA) 20_2.

As in the first embodiment, the semiconductor laser 201 is sequentially provided with a substrate 201, a first cladding layer 202, a first guide layer 203_1, an active layer 204_1, a second guide layer 205_1, and a second cladding layer 206, in which the first cladding layer 202 to the second cladding layer 206 constitute a ridge waveguide. Here, the second cladding layer 206 has a protrusion constituting a ridge portion.

An n-type electrode 208 is provided on the back surface of the substrate 201, and a p-type electrode 209_1 and a pad electrode 210_1 are sequentially provided on the second cladding layer 206 via a contact layer 207_1.

In addition, a diffraction grating 212 is provided at a boundary between the second guide layer 205_1 and the second cladding layer 206, and a heater 213 and a pad electrode 214 are provided near the second cladding layer 206.

The active layer 204_1 is a multiple quantum well (MQW), includes a compressively strained InGaAs well layer and an InGaAsP barrier layer substantially lattice-matched to the InP, and has four periods. The photoluminescence emission wavelength of the MQW is about 1.80 μm, which is a wavelength near the absorption lines of hydrogen chloride (¹H²⁸Cl) and water (¹H₂¹⁶O).

The diffraction grating 212 of the semiconductor laser 20_1 has a Bragg wavelength of 1.80 μm at room temperature.

Other components of the semiconductor laser 20_1 are substantially the same as those in the first embodiment.

The semiconductor optical amplifier (SOA) 20_2 is sequentially provided with the substrate 201, the first cladding layer 202, a third guide layer 203_2, an SOA active layer 204_2, a fourth guide layer 205_2, and the second cladding layer 206, in which the first cladding layer 202 to the second cladding layer 206 constitute a ridge waveguide. The n-type electrode 208 is provided on the back surface of the substrate 201, and a p-type electrode 209_2 and a pad electrode 210_2 are sequentially provided on the second cladding layer 206 via a contact layer 207_2.

Here, in order to constrict the injection current for the semiconductor laser 20_1 and the injection current for the SOA 202, the contact layers 207_1 and 207_2, the p-type electrodes 209_1 and 209_2, and the pad electrodes 210_1 and 210_2 are individually separated from each other, and a part near the upper surface of the second cladding layer 206 is removed.

The substrate 201, the first cladding layer 202, the second cladding layer 206, and the n-type electrode 208 are shared with the semiconductor laser 20_1.

In the SOA 202, the SOA active layer 204_2 is a multiple quantum well (MQW), includes a compressively strained InGaAs well layer and an InGaAsP barrier layer substantially lattice-matched to the InP, and has four periods. The photoluminescence emission wavelength of an MQW 4 is about 1.85 μm.

In the optical semiconductor element 20, the ridge waveguide of the semiconductor laser 20_1 and the ridge waveguide of the SOA 20_2 are optically coupled and connected in the waveguide direction (Y direction in the drawing).

### Effects of Optical Semiconductor Element

The optical semiconductor element 20 according to the present embodiment is mounted on an optical semiconductor module. The optical semiconductor module is sequentially provided with the optical semiconductor element 20 according to the present embodiment, a heat sink, a submount, and a Peltier element.

First, the temperature of the heat sink of the optical semiconductor module is set to 20° C., the injection current for the semiconductor laser 20_1 is set to 100 mA, and the injection current for the semiconductor optical amplifier is set to 250 mA. Next, a heater current is increased from 0 mA to 180 mA, and thus, the wavelength emitted from the semiconductor optical amplifier changes from 1.800 μm to 1.804 μm in about 5 milliseconds.

At this time, a light output decreases from 12 mW to 10 mW. Thus, it is possible to suppress the decrease in light output at the time of wavelength sweep to about 2 mW.

For example, in a case where hydrogen chloride (¹H²⁸Cl) and water (¹H₂¹⁶O) are to be measured, by sweeping the oscillation wavelength of the optical semiconductor element 20 from 1.800 μm to 1.804 μm as described above, it is possible to sweep at least one of the absorption lines for each of hydrogen chloride (¹H²⁸Cl) and water (¹H₂¹⁶O), and it is possible to acquire a gas concentration by analyzing a change in light transmittance caused by the optical absorption. Thus, a plurality of gas species can be measured with one laser.

Semiconductor lasers for gas measurement are desired to have a smaller change in light output associated with a change in wavelength. However, in the semiconductor laser 10 according to the first embodiment, when the temperature around the active layer increases, not only the oscillation wavelength but also the light output decreases.

On the other hand, in the optical semiconductor element 20 according to the present embodiment, a decrease in light output at the time of wavelength sweep caused by an increase in temperature around the active layer of the semiconductor laser 20_1 can be compensated by the SOA, and thus a change in light output can be suppressed.

The optical semiconductor element according to the present embodiment has effects similar to those of the first embodiment, can perform wavelength sweep in a wide wavelength range at high speed, and can suppress a change in light output, thereby allowing for gas measurement with high accuracy.

The present embodiment may provide a configuration in which, in order to suppress heat conduction from the heater of the semiconductor laser to the SOA, a part of the first cladding layer excluding the ridge waveguide, the first guide layer and/or third guide layer, the active layer and/or SOA active layer, and the second guide layer and/or fourth guide layer may be removed between near the heater of the semiconductor laser and the SOA, and a groove 215 may be provided as illustrated in FIGS. 3A and 3B.

This makes the SOA less susceptible to a temperature increase caused by the heater, and facilitates control using the temperature of the heat sink. Therefore, an output of the semiconductor laser can be efficiently amplified and a change in light output can be suppressed, and thus gas measurement can be performed with high accuracy.

### Method of Manufacturing Optical Semiconductor Element

An example of a method of manufacturing the optical semiconductor element 20 according to the present embodiment will be described below.

First, as a layer structure constituting the semiconductor laser 20_1, as in the first embodiment, the first cladding layer (n-type InP) 202, the first guide layer (InGaAsP) 203_1, the active layer (MQW) 204_1, the second guide layer (InGaAsP) 205_1, the second cladding layer (p-type InP) 206, and an InP protective layer are sequentially crystal-grown on the n-type InP substrate 201 by metal-organic vapor phase epitaxy.

Next, the first guide layer (InGaAsP) to the InP protective layer in the region excluding the portion constituting the semiconductor laser 20_1 are removed by etching.

Next, by metal-organic vapor phase epitaxy, the third guide layer (InGaAsP) 203_2, the SOA active layer (MQW) 204_2, the fourth guide layer (InGaAsP) 205_2, and the second cladding layer (p-type InP) are partially regrown sequentially as a layer structure constituting the semiconductor optical amplifier (SOA) 20_2 in the etched region.

Next, the InP protective layer in a portion constituting the semiconductor laser 20_1 is removed, and then the diffraction grating 212 is produced by etching on the upper surface of the second guide layer (InGaAsP) 205_1 in this portion.

Next, the second cladding layer (p-type InP) 206, a contact layer (p-type InGaAs), and the InP protective layer are regrown on the entire surface of a wafer by metal-organic vapor phase epitaxy.

Next, the second cladding layer (p-type InP) 206, the contact layer (p-type InGaAs), and the InP protective layer are processed by dry etching and wet etching to form a ridge portion in the semiconductor laser 20_1 and the SOA 20_2.

Next, in the second guide layer (InGaAsP) 205_1 exposed in the region excluding the ridge portion, a region outside the region where the pad electrodes are arranged in a process to be described later is removed up to a part of the first cladding layer (n-type InP) 202 or the n-type InP substrate 201.

Next, in a region between near the heater 213 of the semiconductor laser 20_1 and the SOA 202, a part of the first cladding layer 202 excluding the ridge waveguide, the first guide layer 203_1 and/or third guide layer 203_2, the active layer 204_1 and/or SOA active layer 204_2, and the second guide layer 205_1 and/or fourth guide layer 205_2 are removed to form the groove 215.

Next, in order to electrically separate the semiconductor laser 20_1 and the SOA 20_2 from each other during current injection, a part of the second cladding layer (p-type InP) 206 near (around) the boundary between the semiconductor laser 20_1 and the SOA 202, the contact layer (p-type InGaAs), and the InP protective layer are removed. As a result, regions to be the contact layer (p-type InGaAs) 207_1 of the semiconductor laser 20_1 and the contact layer (p-type InGaAs) 207_2 of the SOA are formed separately from each other.

Next, an insulating film 211 is accumulated on the entire upper surface of the wafer, and then the insulating film 211 and the InP protective layer on the contact layers (p-type InGaAs) 207_1 and 207_2 of the semiconductor laser 20_1 and the SOA 20_2 are removed.

Next, a metal (AuZnNi or Au) to be the p-type electrodes 209_1 and 209_2 is deposited on the contact layers (p-type InGaAs) 207_1 and 207_2 by resistance heating.

Next, the heater 213 constituted by Pt is formed on the insulating film 211 near the ridge portion by lithography and electron beam deposition.

Next, the pad electrodes 210_1 and 210_2 of the p-type electrodes 209 and the pad electrode 214 of the heater 213, which are constituted by Au, are formed.

Next, the back surface of the n-type InP substrate 201 is polished, and then the n-type electrode 208 is deposited and annealed for electrode formation.

Next, cleavage is performed to form a ridge waveguide structure in which the semiconductor laser 20_1 has a resonator length of 450 μm and the SOA 20_2 has a length of 600 μm.

Lastly, a high-reflection film is deposited on a cleavage surface on the semiconductor laser 20_1 side, and an antireflection film is deposited on a cleavage surface on the SOA 20_2 side.

Thus, the optical semiconductor element 20 is manufactured.

While the embodiments of the present invention show examples in which only the current applied to the heater is changed, it is also possible to change the oscillation wavelength by changing both the current applied to the heater and the injection current.

The embodiments of the present invention show an example in which carbon monoxide (¹²C¹⁶O₂) is to be measured and the oscillation wavelength is set from 2.330 μm to 2.333 μm by using an MQW having a photoluminescence emission wavelength of about 2.33 μm for the active layer, and an example in which hydrogen chloride (¹H²⁸Cl) and water (¹H₂¹⁶O) are to be measured and an emission (oscillation) wavelength is set from 1.800 μm to 1.804 μm by using an MQW having a photoluminescence emission wavelength of about 1.80 μm for the active layer, but the present invention is not limited to these examples. In a case where another gas is to be measured, the oscillation wavelength of the semiconductor laser may be set to another wavelength band in a range from 1.6 to 2.4 μm.

In the MQW, any of InGaAs, InAs, and InGaAsSb can be used for the well layer, and any of InGaAs, InGaAsP, and InGaAsSb can be used for the barrier layer, and it is only required that a laser oscillation wavelength of 1.6 to 2.4 μm is covered. The layer thickness and the period are only required to be in a range in which lattice relaxation does not occur.

Materials used for the cladding layers and the guide layer are only required to be approximately lattice-matched to the InP and have individual functions of the cladding layers and the guide layers. Here, “approximately lattice-matched to the InP” refers to a state in which lattice relaxation does not occur on the InP.

The substrates are not limited to InP substrates, and dielectric substrates such as SiO₂, Si substrates, SOI substrates, or the like can be used by using wafer bonding or the like.

While an example in which the diffraction grating is arranged at the boundary between the second cladding layer and the second guide layer has been described, it is also possible to arrange the diffraction grating at the boundary between the first cladding layer and the first guide layer. The configuration of the diffraction grating (e.g., depth and period) may be set in accordance with the oscillation wavelength of the semiconductor laser.

The embodiments of the present invention show examples of the structures, dimensions, materials, and the like of the components in the configuration, manufacturing method, and the like of the semiconductor laser, but the present invention is not limited thereto. The semiconductor laser is only required to exhibit its functions and achieve its effects.

### INDUSTRIAL APPLICABILITY

Embodiments of the present invention relate to a semiconductor laser and a module element for wavelength sweep, and can be applied to gas measurement.

### REFERENCE SIGNS LIST

10 Semiconductor laser
101 Substrate
102 First cladding layer
104 Active layer
106 Second cladding layer
113 Heater

1.-8. (canceled)

9. A semiconductor laser comprising:
a first cladding layer, an active layer, and a second cladding layer sequentially provided on a substrate;
a ridge portion arranged in a waveguide direction in the second cladding layer; and
a heater arranged adjacent to the ridge portion, wherein an oscillation wavelength of the semiconductor laser is configured to be in a range of 1.6 μm to 2.4 μm.

10. A The semiconductor laser according to claim 9, further comprising:
a first guide layer arranged between the first cladding layer and the active layer;
a second guide layer arranged between the active layer and the second cladding layer;
a diffraction grating arranged at a boundary between the first cladding layer and the first guide layer or a boundary between the second cladding layer and the second guide layer; and
an insulating film arranged on a surface of the second guide layer excluding the ridge portion, wherein the heater is arranged on the insulating film on the surface of the second guide layer.

11. The semiconductor laser according to claim 10, wherein the diffraction grating is arranged at the boundary between the first cladding layer and the first guide layer.

12. The semiconductor laser according to claim 10, wherein the diffraction grading is arranged at the boundary between the second cladding layer and the second guide layer.

13. The semiconductor laser according to claim 10, further comprising:
a pad electrode electrically connected to the heater and arranged on the surface of the second guide layer via the insulating film, wherein the second guide layer, the active layer, and the first guide layer are not provided in a region outside the pad electrode.

14. The semiconductor laser according to claim 10, wherein:
the active layer has a multiple quantum well structure; and
the multiple quantum well structure has a well layer constituted by InGaAs, InAs, or InGaAsSb, and a barrier layer constituted by InGaAs, InGaAsP, or InGaAsSb.

15. The semiconductor laser according to claim 9, wherein the heater is arranged in parallel to the ridge portion.

16. The semiconductor laser according to claim 9, wherein a semiconductor optical amplifier is provided in the waveguide direction.

17. The semiconductor laser according to claim 16, wherein a groove is provided between the heater and the semiconductor optical amplifier.

18. A module element comprising:
a semiconductor laser comprising:
a first cladding layer, an active layer, and a second cladding layer sequentially provided on a substrate;
a ridge portion arranged in a waveguide direction in the second cladding layer; and
a heater arranged adjacent to the ridge portion, wherein an oscillation wavelength of the semiconductor laser is configured to be in a range of 1.6 μm to 2.4 μm
a heat sink; and
a Peltier element.

19. The module element according to claim 18, further comprising:
a first guide layer arranged between the first cladding layer and the active layer;
a second guide layer arranged between the active layer and the second cladding layer;
a diffraction grating arranged at a boundary between the first cladding layer and the first guide layer or a boundary between the second cladding layer and the second guide layer; and
an insulating film arranged on a surface of the second guide layer excluding the ridge portion, wherein the heater is arranged on the insulating film on the surface of the second guide layer.

20. The module element according to claim 19, further comprising:
a pad electrode electrically connected to the heater and arranged on the surface of the second guide layer via the insulating film, wherein the second guide layer, the active layer, and the first guide layer are not provided in a region outside the pad electrode.

21. The module element according to claim 19, wherein:
the active layer has a multiple quantum well structure; and
the multiple quantum well structure has a well layer constituted by InGaAs, InAs, or InGaAsSb, and a barrier layer constituted by InGaAs, InGaAsP, or InGaAsSb.

22. The module element according to claim 18, wherein the heater is arranged in parallel to the ridge portion.

23. The module element according to claim 18, wherein a semiconductor optical amplifier is provided in the waveguide direction.

24. The module element according to claim 23, wherein a groove is provided between the heater and the semiconductor optical amplifier.
